(19) United States
(12) Patent Application Publication
(10) Pub. No.: US 2015/0255474 A1
(43) Pub. Date: Sep. 10, 2015

(54) SEMICONDUCTOR DEVICE AND NONVOLATILE SEMICONDUCTOR STORAGE DEVICE

(71) Applicant: KABUSHIKI KAISHA TOSHIBA, Tokyo (JP)

(72) Inventor: Yoshinori IKEBUCHI, Yokkaichi Mie (JP)

(21) Appl. No.: 14/606,852

(22) Filed: Jan. 27, 2015

Related U.S. Application Data
(60) Provisional application No. 61/948,371, filed on Mar. 5, 2014.
(60) Provisional application No. 62/043,130, filed on Aug. 28, 2014.

(51) Int. Cl. H01L 27/115; H01L 29/49

(52) U.S. Cl. CPC H01L 27/11521; H01L 27/11526; H01L 29/4925

(57) ABSTRACT

A semiconductor device includes a semiconductor substrate, a first insulating film on the semiconductor substrate, a first electrode film on the first insulating film, a second insulating film on the first electrode film, a second electrode film on the second insulating film, an opening extending through the second electrode film and the second insulating film and into the first electrode film, a barrier film over the surfaces of the opening and a portion of the first electrode film exposed within the opening, and a metal film disposed on the barrier film disposed over the surfaces of the opening. The barrier film directly contacts at least a portion of the second insulating film exposed in the opening and the metal film overlies the location where the barrier film directly contacts the second insulating film exposed in the opening.

### CROSS-REFERENCE TO RELATED APPLICATION

This application is based upon and claims the benefit of priority from U.S. Provisional Patent Application No. 61/948,371, filed Mar. 5, 2014, and U.S. Provisional Patent Application No. 62/043,130, filed Aug. 28, 2014; the entire contents of both applications are incorporated herein by reference.

### FIELD

Embodiments described herein relate to a semiconductor device and a nonvolatile semiconductor storage device.

### BACKGROUND

For example, a nonvolatile semiconductor storage device includes a charge accumulation type memory device that stores information by stacking a first insulating film, a first electrode film, a second insulating film, and a second electrode film on a semiconductor substrate, and accumulating a charge in the first electrode film. Simultaneously with the forming of the charge accumulation type memory device, a peripheral device other than the memory device (for example, a select transistor and a peripheral transistor) is formed adjacent to the charge accumulation type memory device by forming a stacked structure in the same manner at the same time as the charge accumulation type memory device is formed. Since it is not necessary to store information in the peripheral device described above, an opening is formed on the second insulating film, and the first electrode film and the second electrode film are electrically short-circuited to one another in the peripheral device.

### BRIEF DESCRIPTION OF THE DRAWINGS

FIG. 1 is an example of a diagram schematically illustrating an electrical configuration of a portion of a memory cell area and a peripheral circuit area of a nonvolatile semiconductor storage device of a first embodiment.

FIG. 2A is a plan view schematically illustrating the memory cell area in the first embodiment.

FIG. 2B is a plan view schematically illustrating a transistor of the peripheral circuit area in the first embodiment.

FIG. 3A is a longitudinal sectional view schematically illustrating the portion of the nonvolatile semiconductor storage device which is cut by a 3A-3A line of FIG. 2A in the first embodiment.

FIG. 3B is a longitudinal sectional view schematically illustrating the portion of the nonvolatile semiconductor storage device which is cut by a 3B-3B line of FIG. 2B in the first embodiment.

FIG. 3C is a longitudinal sectional view schematically illustrating the portion of the nonvolatile semiconductor storage device which is cut by a 3C-3C line of FIG. 2A in the first embodiment.

FIG. 4A, FIG. 5A, FIG. 6A, FIG. 7A, FIG. 8A and FIG. 9A are longitudinal sectional views schematically illustrating one stage of a manufacturing process of the portion of the nonvolatile semiconductor storage device which is cut by the 3A-3A line of FIG. 2A in the first embodiment.

FIG. 4B, FIG. 5B, FIG. 6B, FIG. 7B, FIG. 8B and FIG. 9B are longitudinal sectional views schematically illustrating one stage of the manufacturing process of the portion of the nonvolatile semiconductor storage device which is cut by the 3B-3B line of FIG. 2B in the first embodiment.

FIG. 4C, FIG. 5C, FIG. 6C, FIG. 7C, FIG. 8C and FIG. 9C are longitudinal sectional views schematically illustrating one stage of the manufacturing process of the portion of the nonvolatile semiconductor storage device which is cut by the 3C-3C line of FIG. 2A in the first embodiment.

FIG. 10A is an example of a longitudinal sectional view schematically illustrating the portion of the nonvolatile semiconductor storage device which is cut by the 3A-3A line of FIG. 2A in a second embodiment.

FIG. 10B is an example of a longitudinal sectional view schematically illustrating the portion of the nonvolatile semiconductor storage device which is cut by the 3B-3B line of FIG. 2A in the second embodiment.

FIG. 10C is an example of a longitudinal sectional view schematically illustrating the portion of the nonvolatile semiconductor storage device which is cut by the 3C-3C line of FIG. 2A in the second embodiment.

FIG. 11A, FIG. 12A, FIG. 13A and FIG. 14A are longitudinal sectional views schematically illustrating one stage of the manufacturing process of the portion of the nonvolatile semiconductor storage device which is cut by the 3A-3A line of FIG. 2A in the second embodiment.

FIG. 11B, FIG. 12B, FIG. 13B and FIG. 14B are longitudinal sectional views schematically illustrating one stage of the manufacturing process of the portion of the nonvolatile semiconductor storage device which is cut by the 3B-3B line of FIG. 2B in the second embodiment.

FIG. 11C, FIG. 12C, FIG. 13C and FIG. 14C are longitudinal sectional views schematically illustrating one stage of the manufacturing process of the portion of the nonvolatile semiconductor storage device which is cut by the 3C-3C line of FIG. 2A in the second embodiment.

FIG. 15 is a longitudinal sectional view schematically illustrating the portion of the nonvolatile semiconductor storage device which is cut by the 3B-3B line of FIG. 2B in a third embodiment.

FIG. 16A is a longitudinal sectional view schematically illustrating one stage of the manufacturing process of the portion of the nonvolatile semiconductor storage device which is cut by the 3A-3A line of FIG. 2A in the third embodiment.

FIG. 16B is a longitudinal sectional view schematically illustrating the portion of the nonvolatile semiconductor storage device which is cut by the 3B-3B line of FIG. 2B in the third embodiment.

FIG. 17A is a longitudinal sectional view schematically illustrating the portion of the nonvolatile semiconductor storage device which is cut by the 3A-3A line of FIG. 2A in a fourth embodiment.

FIG. 17B is a longitudinal sectional view schematically illustrating the portion of the nonvolatile semiconductor storage device which is cut by the 3B-3B line of FIG. 2B in the fourth embodiment.

### DESCRIPTION

According to one embodiment, a semiconductor device includes a semiconductor substrate, a first insulating film on the semiconductor substrate, a first electrode film on the first insulating film, a second insulating film on the first electrode film, a second electrode film on the second insulating film, an opening extending through the second electrode film and the second insulating film and into the first electrode film, a barrier film over the surfaces of the opening and a portion of the first electrode film exposed within the opening, and a metal film disposed on the barrier film disposed over the surfaces of the opening. The barrier film directly contacts at least a portion of the second insulating film exposed in the opening and the metal film overlies the location where the barrier film directly contacts the second insulating film exposed in the opening.

According to another embodiment, the semiconductor device includes, on a first area of a semiconductor substrate: a first insulating film, a first electrode film on the first insulating film, a second insulating film on the first electrode film, a second electrode film on the second insulating film, and a first opening extending through the second electrode film and the second insulating film and into the first electrode film, and having a first opening width; on a second area of the semiconductor substrate, a third insulating film, a third electrode film on the third insulating film, a fourth insulating film on the third electrode film, a fourth electrode film on the fourth insulating film, and a second opening extending through the fourth electrode film and the fourth insulating film, and having a second opening width which is less than the first opening width; a first barrier film and a first metal film in the first opening; and a first material, different than the first metal film, in the second opening. On the first area of the semiconductor substrate, the first barrier film overlies at least a portion of the second insulating film exposed within the opening and the metal film overlies the barrier film overlying the portion of the second insulating film exposed within the opening.

According to still another embodiment, the semiconductor device includes a memory cell and a peripheral transistor on a semiconductor substrate. The peripheral transistor includes a first insulating film on the semiconductor substrate, a first electrode film of a first conductivity type on the first insulating film, a second insulating film on the first electrode film, a second electrode film on the second insulating film, an opening extending through the second electrode film and the second insulating film, and into the first electrode film, and a first material filling the opening and contacting the first electrode film. At least a portion of the first material adjacent to the first electrode film is of the first conductivity type, and a barrier metal film and a metal film that are formed on the first material. The memory cell includes a third insulating film on the semiconductor substrate, a third electrode film of the first conductivity type on the third insulating film, a fourth insulating film on the third electrode film, a second material on the fourth insulating film, and a fourth electrode film on an upper face of the second material. A film thickness of a portion on an upper face of the second electrode film of the first material is equal to a film thickness of the second material.

Hereinafter, several embodiments will be described. The same reference signs or the similar reference signs are attached to the same portions or the similar portions of configuration elements between the respective embodiments, descriptions thereof are omitted as necessary, and the feature portions of the respective embodiments will be mainly described.

### First Embodiment

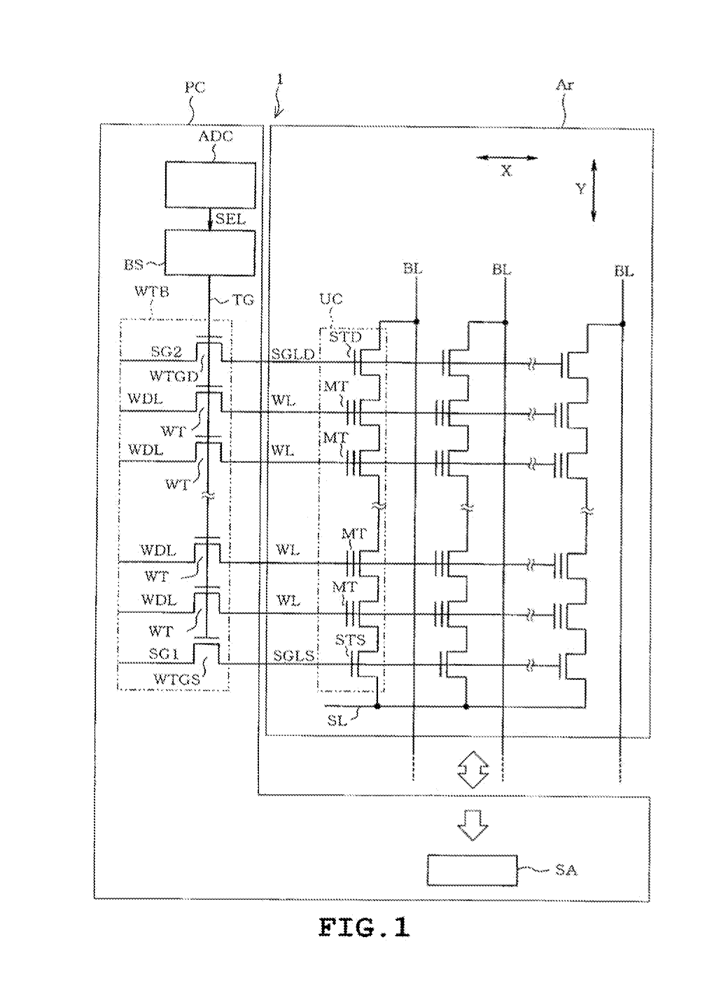

Hereinafter, a semiconductor device which is applied to a NAND type flash memory device according to a first embodiment, will be described with reference to FIG. 1 to FIG. 9C. Furthermore, the drawings are schematic, and thus a relationship between a thickness and a planar dimension, a thickness ratio of each layer and the like do not necessarily match sizes which are in an actual device. Moreover, an upper and lower direction and a left and right direction in the drawings show the relative directions which are obtained when a circuit formation face side in a semiconductor substrate described later is assumed as a top, and thus the directions thereof do not necessarily match the directions in case of a gravitational acceleration direction as a reference.

FIG. 1 is a block diagram schematically illustrating an electrical configuration of the NAND type flash memory device. As shown in FIG. 1, a NAND type flash memory device 1 includes a memory cell array Ar in which many memory cells are located in a matrix layout, and a peripheral circuit PC which performs reading processing, writing processing, and erasing processing and the like in the respective memory cells of the memory cell array Ar.

In the memory cell array Ar within a memory cell area, a plurality of cell units UC are located. The cell unit UC includes a select transistor STD which is connected to a bit line BL side, a select transistor STS which is connected to a source line SL side, and memory cells MT, for example, 64 memory cells MT, which are connected in series between the two select transistors STD and STS. Furthermore, a dummy transistor may be located between the select transistor STD and the memory cell MT adjacent to the select transistor STD, and the dummy transistor may be located between the select transistor STS and the memory cell MT adjacent to the select transistor STS.

A block is configured n columns of cell units UC spaced apart in an X direction (the left and right direction in FIG. 1). The memory cell array Ar is configured as a plurality of the blocks disposed in a Y direction (the upper and lower direction in FIG. 1). Moreover, in order to simplify the description, only one block is shown in FIG. 1.

A peripheral circuit area is located on the periphery of the memory cell area, and the peripheral circuit PC is thus positioned on the periphery of the memory cell array Ar. The peripheral circuit PC includes an address decoder ADC, a sense amplifier SA, a boosting circuit (booster circuit) BS mounting a charge pump circuit, a transfer transistor portion WTB and the like. The address decoder ADC is electrically connected to the transfer transistor portion WTB through the boosting circuit BS.

The address decoder ADC selects one block according to an address signal which is input thereto from the outside thereof. The boosting circuit BS boosts a drive voltage which is supplied from the outside thereof when a select signal of the block is given, and supplies a predetermined voltage to transfer gate transistors WTGD, WTGS, and WT through a transfer gate line TG.

The transfer transistor portion WTB includes the transfer gate transistor WTGD, the transfer gate transistor WTGS, the word line transfer gate transistor WT and the like. A transfer transistor portion WTB is provided for each block.

In the transfer gate transistor WTGD, one of a drain and a source thereof is connected to a select gate driver line SG2, and the other of the drain and the source thereof is connected to a select gate line SGLD. In the transfer gate transistor WTGS, one of the drain and the source thereof is connected to a select gate driver line SG1, and the other of the drain and the source thereof is connected to a select gate line SGLS. Furthermore, in the transfer gate transistor WT, one of the drain and the source thereof is connected to each word line drive signal line WDL, and the other of the drain and the source thereof is connected to each word line WL which is located within the memory cell array Ar.

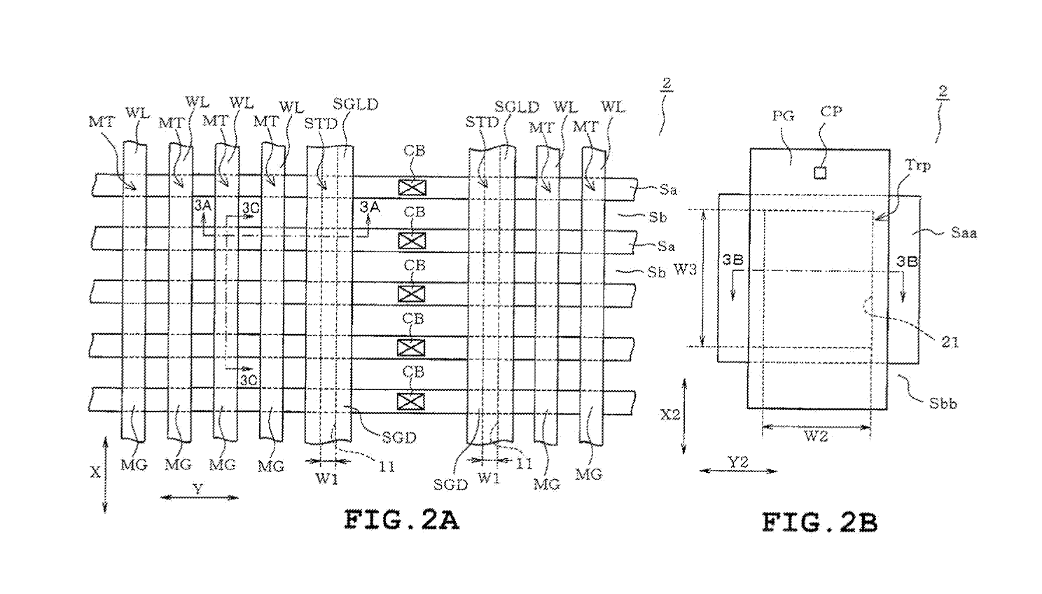

In the plurality of the cell units UC that are disposed in the X direction, each gate (SGD in FIG. 2A) of the select transistors STD is electrically connected to the select gate line SGLD. Each gate electrode of the select transistors STS is electrically connected to the select gate line SGLS. The source sides of the select transistors STS are commonly connected to the source line SL. The memory cells MT in the plurality of the cell units UC that are disposed in the X direction are electrically connected to the gates (MG in FIG. 2A) by the word line WL, respectively.

The gates of the respective transfer gate transistors WTGD, WTGS, and WT, are commonly connected to each other by the transfer gate line TG, and the respective transfer gate transistors WTGD, WTGS, and WT, are connected to a boosting voltage supply terminal of the boosting circuit BS. The sense amplifier SA is connected to the bit line BL, and is connected to a latch circuit that temporarily saves data at the time of reading out of the data.

FIG. 2A shows an exemplary layout pattern of a portion in the memory cell area, and FIG. 2B shows an exemplary layout of the portion in the peripheral circuit area. The peripheral circuit PC and the memory cell array Ar are configured within a semiconductor substrate 2. The semiconductor substrate 2 is, for example, a p-type single crystal silicon substrate.

As shown in FIG. 2A, in the memory cell area of the semiconductor substrate 2, device isolation areas Sb are formed to extend in the Y direction of FIG. 2A. The device isolation area Sb is configured by filling a trench that is formed along the Y direction with an insulating film, and forms the device isolation area having a so-called STI (shallow trench isolation) structure.

A plurality of the device isolation areas Sb are formed at a predetermined spacing in the X direction of FIG. 2A. Thus, a device area Sa is formed to extend along the Y direction of FIG. 2A between adjacent element isolation regions Sb, and a plurality of the device areas Sa are formed spaced apart in the X direction in a surface layer portion of the semiconductor substrate 2.

The word line WL is formed to extend along the direction (the X direction of FIG. 2A) intersecting at right angles with the device areas Sa. A plurality of word lines WL are formed spaced apart at a predetermined gap in the Y direction of FIG. 2A. On the device area Sa where a word line WL overlies (extends over), the gates MG of the memory cells (memory cell transistors) MT are formed.

A NAND string is configured with the plurality of memory cells MT which are adjacent to one another the Y direction of FIG. 2A. The select transistors STD are respectively located to be adjacent to the memory cells MT at both end portions of the NAND string in the Y direction. A plurality of the select transistors STD are located in the X direction, and the gates SGD in the plurality of select transistors STD are electrically connected through the select gate line SGLD. Furthermore, on the device area Sa underlying the select gate line SGLD, the gates SGD of the select transistors STD are formed.

On the device area Sa between the select transistors STD in two of the adjacent blocks, a bit line contact CB is formed. The bit line contact CB is the contact that electrically connects the bit line BL which is formed to extend in the Y direction over the device area Sa (not shown in FIG. 2A: see FIG. 1), to the device area Sa of the semiconductor substrate 2.

FIG. 2B shows an example of the layout of a transistor Trp in the peripheral circuit area. In the semiconductor substrate 2, a device isolation area Sbb is formed in the peripheral circuit area. The trench is formed in a circumference thereof so as to leave a device area Saa having a rectangular shape, and the device isolation area Sbb is configured by filling the trench with an insulating film. The device isolation area Sbb is a device isolation area having the so-called STI (shallow trench isolation) structure.

The transistor Trp is configured using the device area Saa having the rectangular shape in a X2 direction and a Y2 direction, and includes a gate PG that is formed so as to cross and extend over the device area Saa in a certain direction (the X2 direction in FIG. 2B). That is, the gate PG is formed so as to project over the device area Saa in the X2 direction and over adjacent regions of the device isolation area Sbb on opposite sides of the device area.

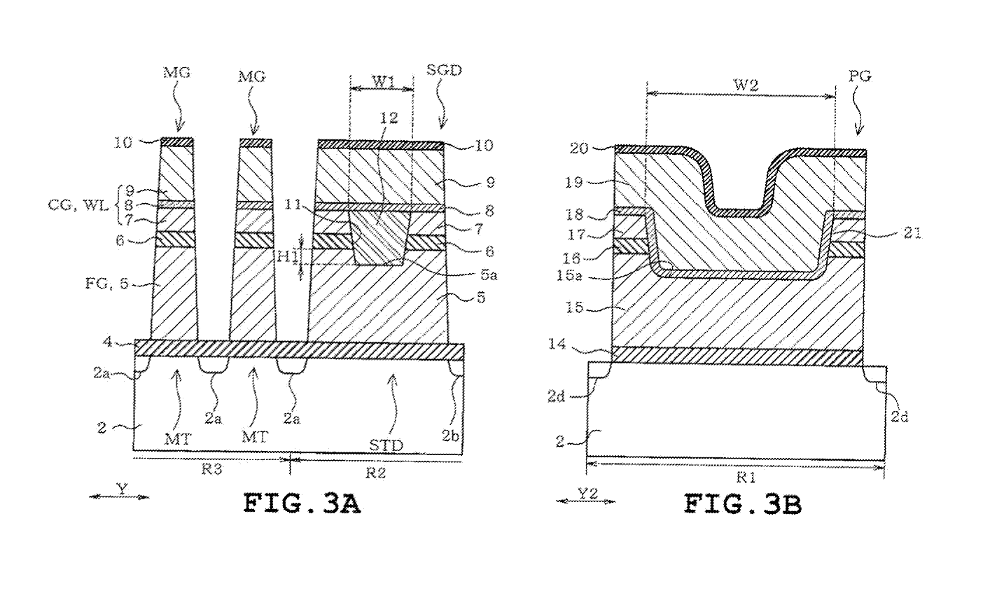

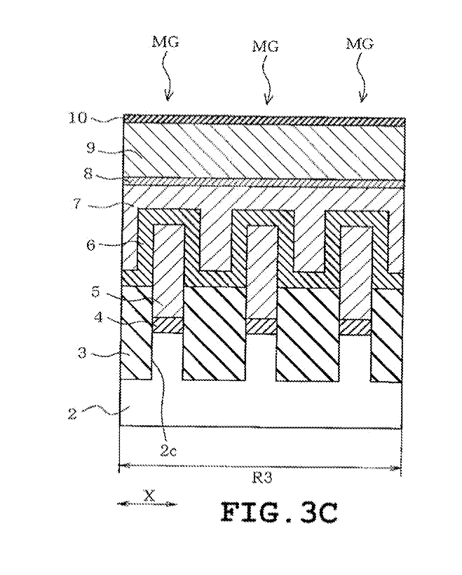

The transistor Trp includes a source and drain area (see 2d of FIG. 3B) that is formed to diffuse, for example, n-type impurities, within the device area Saa at both sides of the gate PG. Moreover, a gate contact CP is formed to come in contact therewith on the gate PG, but is planarly positioned on the device isolation area Sbb outside of the device area Saa.

FIG. 3A is an exemplary cross-section of the memory cell MT and the select transistor STD which are configured in the memory cell area taken at section 3A-3A of FIG. 2A. FIG. 3B is an exemplary cross-sectional structure of the transistor Trp which is configured in the peripheral circuit area taken at section 3B-3B of FIG. 2B. Additionally, FIG. 3C schematically shows a longitudinal sectional view of the portion taken along a 3C-3C line of FIG. 2A. In a cross section of the memory cell area shown in FIG. 3C, trenches 2c are formed inwardly of the surface of the semiconductor substrate 2, and a device isolation film 3 is embedded within the trench 2c. The device isolation film 3 is formed of an insulating film (for example, a silicon oxide film). The device isolation film 3 is formed to protrude from an upper face of the semiconductor substrate 2. A plurality of these device isolation films 3 are formed to be spaced in the X direction. On the upper face of the semiconductor substrate 2 between the adjacent device isolation films 3, a gate insulating film 4 is formed. The gate insulating film 4 is formed, for example, with a silicon oxide film. On the upper face of the gate insulating film 4, the gates MG of the memory cells MT are respectively formed. On the gate insulating film 4, the gate MG is configured by stacking a polysilicon film 5, an inter-electrode insulating film 6, a polysilicon film 7, a tungsten nitride (WN) film 8, and a tungsten (W) film 9 in this order, and a silicon nitride film 10 is formed as a cap film on the tungsten film 9.

In the cross section shown in FIG. 3C, the polysilicon film 5 is formed to extend upwardly from an upper face position of the device isolation film 3, and the inter-electrode insulating film 6 is formed along the upper face and the upper side face of the polysilicon film 5, and on the upper face of the device isolation film 3.

Similarly, in the cross section of the memory cell area shown in FIG. 3A, the gate insulating film 4 is formed on the upper face of the semiconductor substrate 2. On the upper face of the gate insulating film 4, the gates MG in the plurality of memory cells MT, and the select gate SGD in the select transistor STD for selecting the memory cell MT, are formed. As shown in FIG. 3A, a distance or spacing between the adjacent gates MG is a first predetermined gap, and the distance or spacing between the gate MG and the adjacent gate SGD is as a second predetermined gap.

The memory cell MT is configured to include the gate MG, and a source and drain area 2a which is formed in the surface layer of the semiconductor substrate 2 on both sides of the gate MG in the Y direction. The memory cell MT is formed on a third area R3 of the semiconductor substrate 2. A plurality of memory cells MT are formed to be adjacent to one another in the Y direction.

As described above, the gate MG of the memory cell MT is configured by stacking the polysilicon film 5, the inter-electrode insulating film 6, the polysilicon film 7, the tungsten nitride (WN) film 8, and the tungsten (W) film 9 in that order, on the gate insulating film 4, and forming a silicon nitride film 10 as a cap film on the tungsten film 9.

The polysilicon film 5 is configured as a p-type doped film, using for example, p-type impurities (for example, boron (B)), and is formed as an electrode film, i.e., a film which is then patterned into individual electrodes. The polysilicon film 5 is configured as a floating electrode FG within the memory cell MT. For example, if boron (B) is used as the dopant, the p-type impurities are doped, for example, with a concentration of 1×10²⁰ to 1×10²² [atoms/cm³], approximately by either diffusion of the dopant or ion implantation of the dopant into the polysilicon film 5. N-type impurities (for example, phosphorus (P)) may be also introduced, and the type of dopant is not limited thereto. Furthermore, the impurity concentration of the polysilicon film may be measured by a SIMS (Secondary Ion Mass Spectrometry) analysis or the like.

The polysilicon film 7 is formed as an electrode film which is configured as p-type doped and the p-type impurities (for example, boron (B)) are introduced thereto in the same manner as with the polysilicon film 5. Furthermore, as the polysilicon film 7, a form using the polysilicon film into which the p-type impurities are introduced, is shown, but the polysilicon film into which the n-type impurities (for example, phosphorus (P)) are introduced, may be used, and is not limited thereto.

The tungsten nitride film 8 is formed as a so-called barrier metal film, and the tungsten film 9 is formed as a metal film. The polysilicon film 7, the tungsten nitride film 8, and the tungsten film 9 functions as a control electrode CG, and a word line WL.

The inter-electrode insulating film 6 is configured using the film which is obtained by replacing, for example, an ONO (Oxide-Nitride-Oxide) film, or an NONON (Nitride-Oxide-Nitride-Oxide-Nitride) film, or an intermediate nitride film (Nitride) between the ONO films or the NONON films, with an insulating film including high dielectric constant properties.

In the surface layer portion of the semiconductor substrate 2, between the gates MG and MG, and between the gates SGD and MG, the source and drain areas 2a are provided, and between the gates SGD and SGD (rightmost end position of FIG. 3A: corresponding to a bottom of the bit line contact CB of FIG. 2A), a drain area 2b is provided.

The gate SGD of the select transistor STD is formed to have substantially the same structure as the gate MG of the memory cell MT, and is formed on a second area R2 of the semiconductor substrate 2 adjacent to, and at the periphery of, the memory cell region of the third area R3.

On the gate insulating film 4, the gate SGD includes a stacked structure of a polysilicon film 5, the inter-electrode insulating film 6, the polysilicon film 7, the tungsten nitride film 8, and the tungsten film 9 in that order. On the tungsten film 9, the silicon nitride film 10 is further stacked.

In the gate SGD, an opening 11 of a Y direction-width W1 is provided in a center portion of the polysilicon film 7 and the inter-electrode insulating film 6, and a concave portion 5a is formed in an upper portion of the polysilicon film 5. Furthermore, the opening 11 is formed so that the Y direction-width W1 is shorter in the direction of the underlying semiconductor substrate 2 direction.

A polysilicon film 12 as a first material is formed so as to fill up the concave portion 5a and the opening 11 on the polysilicon film 5. Here, the polysilicon film 12 is configured with a low dopant concentration, in comparison with, for example, the polysilicon films 5 and 7. Since the polysilicon film 12 is interposed between the polysilicon film 5 and the polysilicon film 7, for example, if p-type impurities are introduced into the polysilicon film 7, and p-type impurities are introduced into the polysilicon film 5, by performing heat processing, although the polysilicon film 12 is temporarily non-doped at the time of formation thereof, the dopants in the polysilicon films 5 and 7 are diffused into the polysilicon film 12.

Therefore, there is a case where the dopants which are introduced into the polysilicon films 5 and 7, are diffused throughout the polysilicon film 12. In this case, the polysilicon film 12, and the polysilicon films 5 and 7 are formed of the same conductivity type. Moreover, the concentration of the dopant in the polysilicon film 12 is less than the concentration of the dopant in the polysilicon films 5 and 7.

The upper face of the polysilicon film 12 is formed to be flush with the upper face of the polysilicon film 7, and the tungsten nitride film 8 is formed on the upper faces of the polysilicon films 7 and 12. The polysilicon film 12 is electrically connected through the opening 11, between the polysilicon film 5, the polysilicon film 7, and the tungsten nitride film 8. The tungsten nitride film 8 is formed in substantially the flat state above the polysilicon film 12 in the concave portion 5a.

Next, referring to FIG. 3B, the structure of the transistor Trp of the peripheral circuit area will be described. The stacked structure on the semiconductor substrate 2 of the transistor Trp in the peripheral circuit area is substantially the same as the stacked structure of the select transistor STD described above, and is formed on a first area R1 which is different from the second area R2 and the third area R3 of the semiconductor substrate 2. Furthermore, for convenience of description, in FIG. 3B, substantially the same films as described with respect to in FIG. 3A, is shown by adding “10” to element numbers 4 to 10 which are used in FIG. 3A, and thus attaching reference signs 14 to 20 thereto in FIG. 3B, respectively. Therefore, the film shows the film in which reference sign numerals are different but a main material thereof is the same. For example, although the underlying film layer material may be the same as the corresponding film in FIGS. 3A and 3C, dopants and the like which are introduced into the film layer may be different. Thus, in FIGS. 3A and 3C the polysilicon film 5 is doped to be p-type but the polysilicon film 15 of FIG. 3B is doped to be n-type.

In the forming area R1 of the transistor Trp, the semiconductor substrate 2 is processed, and thus, the structure in which the planar circumference of the device area Saa is surrounded by the device isolation area Sbb, is made (see FIG. 2B). In the forming area of the transistor Trp, a gate insulating film 14 is formed on the upper face of the semiconductor substrate 2. Since voltage withstand properties vary according to kinds of the transistor Trp, the gate insulating film 14 is formed thicker film thickness than a transistor whose voltage withstand properties are higher than the predetermined value.

On the gate insulating film 14, the gate PG is formed. The gate PG is configured by stacking an n-type polysilicon film 15, an inter-electrode insulating film 16, a polysilicon film 17, a tungsten nitride (WN) film 18, and a tungsten (W) film 19 in this order, on the gate insulating film 14. Moreover, a silicon nitride film 20 is formed on the tungsten film 19.

The polysilicon film 15 is configured with polysilicon into which n-type impurities (for example, phosphorus (P) or arsenic (As)) are introduced. The form in which the n-type impurities are introduced into the polysilicon film 15, is shown, but is not limited thereto. The p-type impurities may be introduced into the polysilicon film 15. As an example, in the polysilicon film 15, there is the case where both of the n-type impurities and the p-type impurities are doped. In this case, the polysilicon film 15 includes, as a dopant, for example, at least one of phosphorus (P) or arsenic (As), and boron (B. As an n-type dopant in the polysilicon film 15, phosphorus or arsenic is doped, for example, at a concentration of 1×10²⁰ to 1×10²² [atoms/cm³], approximately. Moreover, in the polysilicon film 15, for example, as a p-type dopant boron (B) is provided at a concentration of 1×10¹⁹ [atoms/cm³], approximately. In this case using both an n and a p type dopant, the polysilicon film 15 becomes the n-type as a conductivity type.

The polysilicon film 17 is the same conductivity type as the polysilicon film 7. The conductivity type of the polysilicon film 17 is configured simultaneously with that of the polysilicon film 7, and for example p-type impurities (for example, boron (B)) are introduced therein. A polysilicon film 7, 17 in which p-type impurities are introduced is describes, but n-type impurities may be introduced, and the dopant type is not limited to p-type.

In the gate PG, an opening 21 is provided through the center portion of the polysilicon film 17 and the inter-electrode insulating film 16, and the opening extends into a concave portion 15a in the upper portion of the polysilicon film 15 at the center portion thereof. Furthermore, the opening 21 is formed so that a Y direction-width W1 is shortened toward the lower direction (semiconductor substrate 2 direction) of the opening, i.e., it is tapered.

The tungsten nitride film 18 and the tungsten film 19 are embedded within the opening 21 and the concave portion 15a. Hereby, the tungsten nitride film 18 is formed to contact the side face of the polysilicon film 17, and the side face of the inter-electrode insulating film 16. The Y2 direction-width W2 of the opening 21 is formed to be larger than the Y direction-width W1 of the opening 11. Moreover, as shown in FIG. 2B, there are many cases where the Y2 direction-width W2 of the opening 21 is narrower than an X2 direction-width W3 of the opening 21. In addition, there are many cases where the Y2 direction width of the gate PG of the peripheral transistor Trp, is wider than the width of the gate SGD of the select transistor STD.

As a result, in a manufacturing stage, by increasing the width of the opening 21 of the peripheral transistor Trp in accordance with the extent of the gate width thereof, it is possible to reduce contact resistance between the polysilicon film 15 and the tungsten nitride film 18.

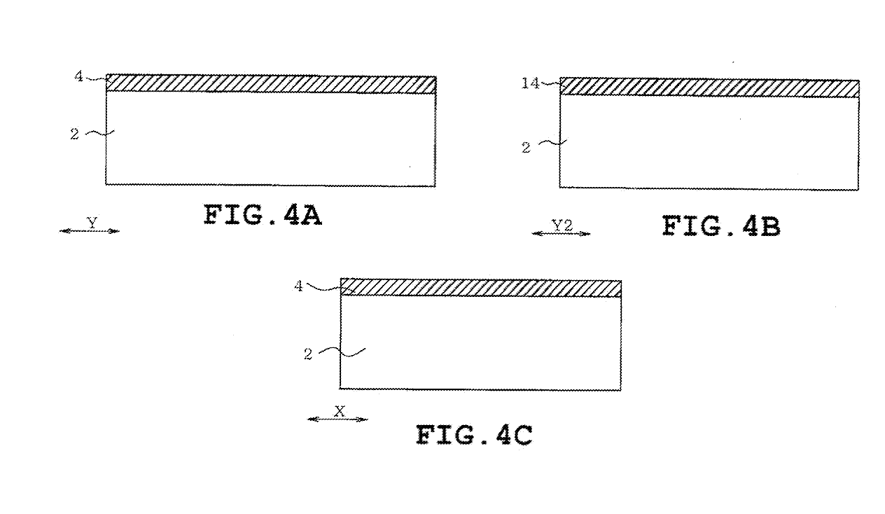

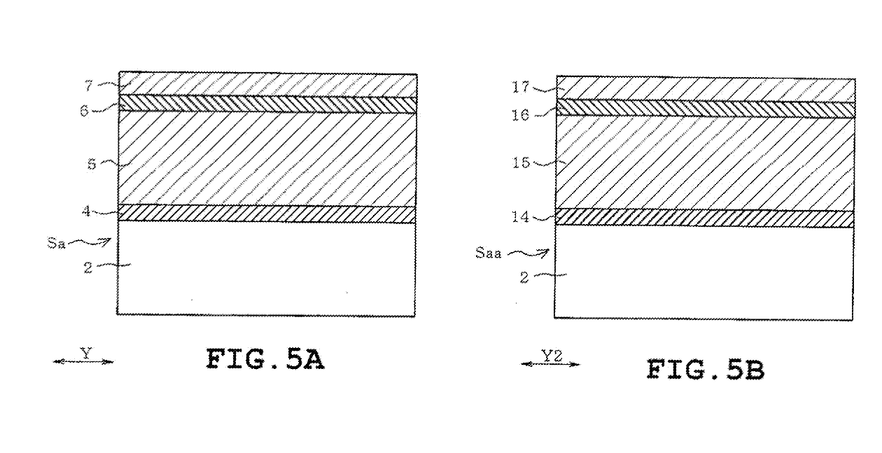

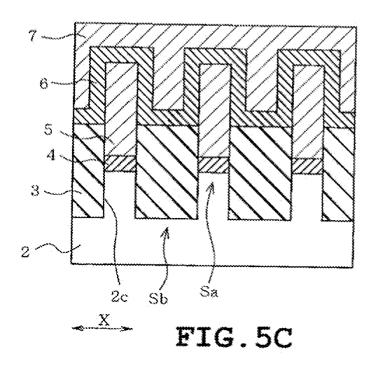

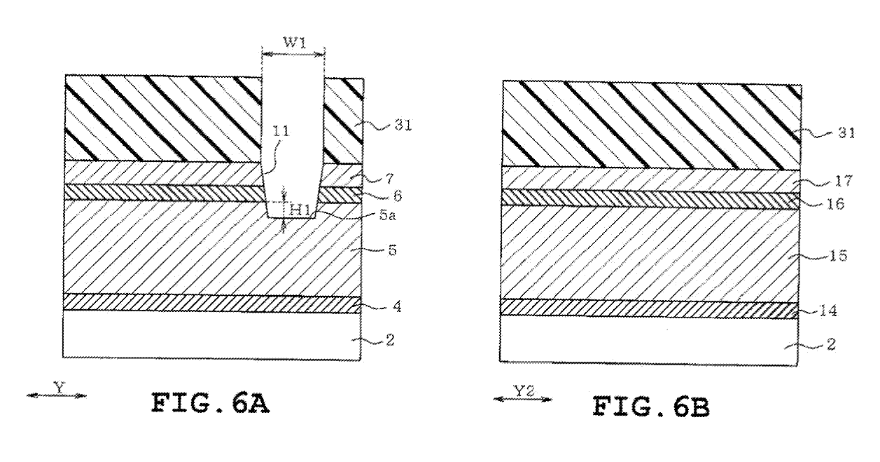

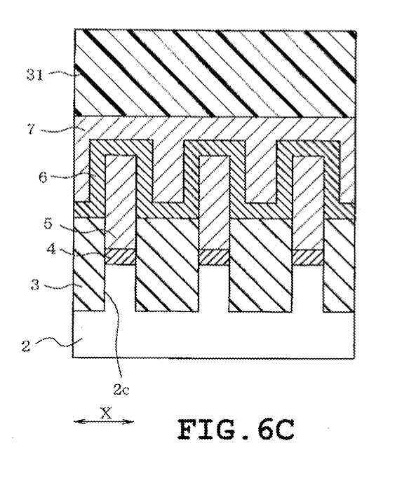

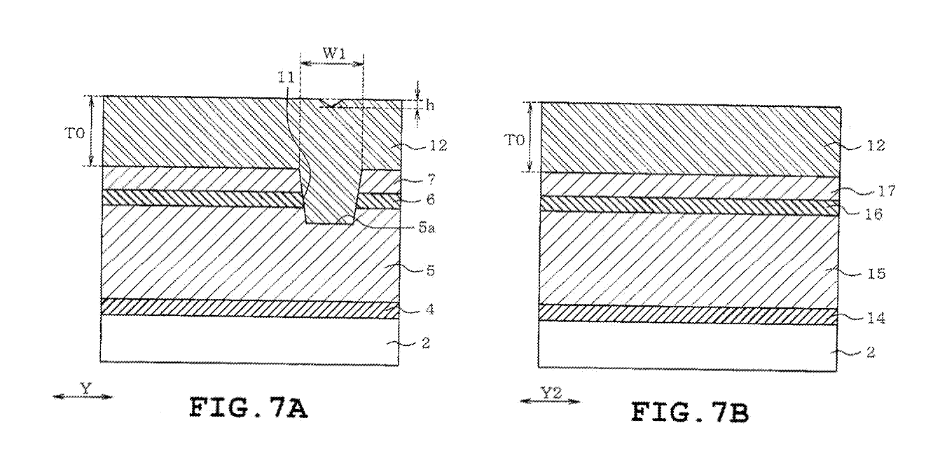

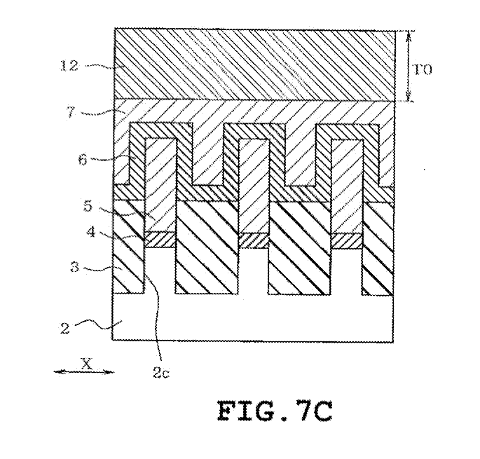

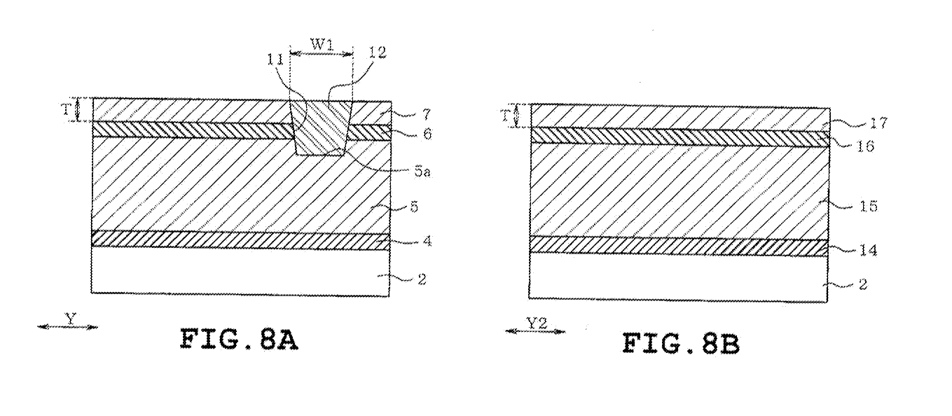

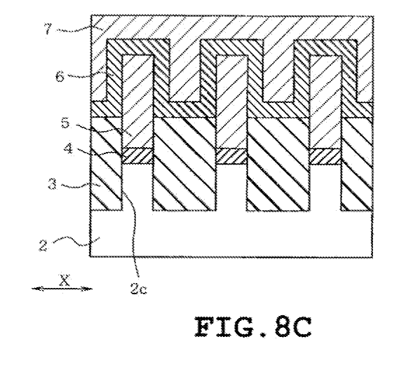

Next, an example of a manufacturing process to form the structure shown in FIG. 3A and FIG. 3B, will be described with reference to FIG. 4A to FIG. 9C. Furthermore, the feature portions will be mainly described in the following description, but other processes may be added between each of processes if it is the general process, and it is possible to delete or substitute some processes as necessary. Additionally, FIG. 3C is a cross section schematically illustrating the cross section along the X direction of FIG. 2A, but when the memory cell MT is manufactured, first, the cross-sectional structure which is shown in FIG. 3C, is formed along the Y direction, and thereafter, the processes which are shown in the subsequent drawings from FIG. 4A, are performed.

As shown in FIG. 4A to FIG. 4C, the gate insulating films 4 and 14 of a predetermined film thickness, are formed on the upper face of the semiconductor substrate 2. For example, when the silicon oxide film is used as the gate insulating films 4 and 14, it is possible to form the gate insulating films 4 and 14, for example, using a thermal oxidation method by raising the temperature of the substrate 2 in an oxygen ambient and convert the exposed silicon into silicon dioxide. Furthermore, the gate insulating films 4 and 14 are separately formed when the thicknesses thereof are different from each other.

As shown in FIG. 5A to FIG. 5C, on the upper faces of the gate insulating films 4 and 14, the polysilicon films 5 and 15 are deposited, for example, using a CVD method. At this time, the polysilicon film 5 is formed by introducing the p-type impurities (for example, boron (B)) thereinto, and the polysilicon film 15 is formed by introducing the n-type impurities (for example, phosphorus (P)) thereinto.

As a forming method, for example, after once depositing the polysilicon into which the impurities are not introduced, by forming a resist mask (not shown) using a photolithography method, and implanting appropriate dopants using an ion implantation method, the p-type impurities (for example, boron (B)) are introduced into the polysilicon film 5. Thereafter, the mask is removed, and a new mask is applied and photolithographically patterned, and the n-type impurities (for example, phosphorus (P)) are implanted only into the polysilicon film 15.

Moreover, as another method, for example, after once depositing the polysilicon film 5 while simultaneously introducing the p-type dopants onto the gate insulating films 4 and 14, the polysilicon film 5 other than in the memory cell area is removed. Subsequently, after forming the polysilicon film 15 on the gate insulating films 4 and 14 while introducing n-type dopants by the same method, the polysilicon film 15 formed in the memory cell area is removed. Even when this method is used, the polysilicon film 5 is formed by introducing the p-type dopants (for example, boron (B)) thereinto, and the polysilicon film 15 may be formed by introducing the n-type dopants (for example, phosphorus (P)) thereinto.

Next, by forming a silicon nitride film as a hard mask (not shown) or the like on the upper faces of the polysilicon films 5 and 15, and anisotropic etching the surface layers of the polysilicon films 5 and 15, the gate insulating films 4 and 14, and the semiconductor substrate 2, the device isolation trenches 2c are formed in the memory cell area.

Thereafter, in the memory cell area, the device isolation film 3 is formed within the device isolation trench 2c, for example, using the CVD method, or a spin on film deposition method or the like, and thereby the device isolation area Sb is formed. The areas which are divided by the device isolation areas Sb, may be formed as the device area Sa. Furthermore, although not shown, the device isolation area Sbb of the peripheral circuit area is formed at the same time in the same process, and hereby, it is possible to form the device area Saa in the semiconductor substrate 2.

Therefore, the inter-electrode insulating films 6 and 16, are simultaneously formed on the upper faces and the side faces of the polysilicon films 5 and 15 and the exposed surfaces of the device isolation film 3 between adjacent portions of the polysilicon film 5. For example, when the ONO film is formed as an inter-electrode insulating film, it is possible to form the inter-electrode insulating film, for example, using the CVD method. Furthermore, as a second electrode film, the polysilicon films 7 and 17 are simultaneously formed to a predetermined film thickness so as to cover the inter-electrode insulating films 6 and 16.

As shown in FIG. 6A to FIG. 6C, in the area corresponding to the portion (for example, center portion) of the gate SGD of the select transistor STD, the opening 11 and the concave portion 5a are formed by forming a resist mask 31 using photolithography technology, and anisotropic ally etching polysilicon films 5 and 7 and inter-electrode insulating film 6. In this processing, by applying a resist 31, and patterning the resist 31, the opening 11 is formed in the portion of the resist corresponding to the area of the select gate SGD in the memory cell area. For example, using an RIE (Reactive Ion Etching) method, the opening 11 of the predetermined width W1 (for example, 40 nm (for example, a range of 40 nm to 50 nm)), is formed by etching the polysilicon film 7, and the inter-electrode insulating film 6. Furthermore, the concave portion 5a of a predetermined depth H1 (depth to a bottom face of the concave portion 5a from a surface of the polysilicon film 5), is formed in the polysilicon film 5. After the etching processing, the surface of the polysilicon film 5, and the surfaces of the opening 11 and the concave portion 5a, are wet cleaned.

Next, as shown in FIG. 7A to FIG. 7C, so as to fill up the upper face of the polysilicon film 7 and an inside of the concave portion 5a, the p-type polysilicon film 12 is formed in a predetermined film thickness T0 (for example, 40 nm), for example, using a low pressure CVD method. As the forming method, for example, the polysilicon into which the dopant is not introduced is first deposited. Additionally, the polysilicon film 12 may be deposited while introducing the p-type dopant (for example, boron (B)) thereinto.

In this case, the film thickness T0 at the time of the film formation of the polysilicon film 12, is selected to be larger than ½ of the dimension of the width W1 of the opening 11 (T0>W1/2). For example, when the width W1 of the opening 11 is 40 nm to 50 nm approximately, the film thickness T0 of the polysilicon film 12 is larger than 20 nm to 25 nm, and may be 35 nm or more, sufficiently in consideration of process capability.

In the upper face of the polysilicon film 12 after the film formation, a slight level difference “h” is generated in the position corresponding to the concave portion 5a, but a dimension h of the level difference is sufficiently small in comparison with the depth H1 of the concave portion 5a, and the dimension h may be, for example, 10 nm or less.

Next, as shown in FIG. 8A to FIG. 8C, the polysilicon film 12 of the memory cell area and the peripheral circuit area is etched by the RIE method, and the upper portion of the polysilicon film 12 is removed. Thus, the polysilicon film 12 remains within the opening 11 of the select transistor STD and the concave portion 5a. In FIG. 8A to FIG. 8C, the state where the polysilicon film 12 is completely removed from the upper of the polysilicon films 7 and 17, is shown, but it not limited thereto in particular. Moreover, at the time of the etching processing, it is possible to make the film thickness thin by etching the upper faces of the polysilicon films 7 and 17.

Hereby, in the structure shown in FIG. 8A to FIG. 8C, as necessary, the film thickness of the polysilicon films 7 and 17, becomes a film thickness T of the polysilicon films 7 and 17 which is an initial film thickness at the time of the film formation, or the thickness T which is obtained from thinning the polysilicon films 7 and 17 in comparison with the initial thickness thereof at the time of the film formation.

When the etching processing is performed using anisotropic etching, there is the case where the slight level difference which is generated at the time of the film formation of the polysilicon film 12, remains even after the etching processing. However, the level difference dimension of the polysilicon film 12 after the etching processing, is substantially the same as the level difference dimension h at the time of the film formation. Hereby, the polysilicon films 7 and 12 are formed in the state where the inside of the opening 11 and the concave portion 5a is filled, and in the state where the upper face is substantially flat.

As shown in FIG. 9A to FIG. 9C, in the peripheral circuit area, using a photolithographically patterned resist and anisotropic etching, the opening 21 and the concave portion 15a are formed. Specifically, by applying a resist 32, and patterning the resist 32, the opening is formed in the area corresponding to the gate PG portion of the peripheral transistor Trp of the peripheral circuit area, and the opening 21 and the concave portion 15a are formed by anisotropic etching, for example, using the RIE method. At this time, the width dimension W2 of the opening 21, may be set to be wider than the width W1 described above, and it may be, for example, 150 nm or more. Preferably, it may be, for example, 200 nm approximately. Therefore, at the time of forming the tungsten nitride film 18 by sputtering, it is easily formed within the upper face of the concave portion 15a of the polysilicon film 15. Furthermore, the depth dimension of the concave portion 15a may be deeper or shallower than the depth H1 described above.

Next, the resist 32 is removed, and the tungsten nitride films 8 and 18, and the tungsten films 9 and 19, are formed in that order by a sputtering method on the upper faces of the polysilicon films 7, 12, 15 and 17 yielding the structure shown in FIG. 3A to FIG. 3C. The tungsten nitride films 8 and 18 function as a barrier metal film, and the films 8 and 18 are formed simultaneously. Moreover, the tungsten films 9 and 19 function as a metal film, and the films 9 and 19 are formed simultaneously. Here, in the memory cell area, since the upper face of the polysilicon film 7 is formed in substantially the flat state, the tungsten nitride film 8 may be formed in a uniform film thickness.

Hereby, the tungsten films 9 and 19 are formed over the tungsten nitride films 8 and 18, respectively, and reaction between the tungsten films 9 and 19 and the polysilicon films 7 and 17, respectively is suppressed.

Subsequently, as shown in FIG. 3A to FIG. 3C, after the silicon nitride films 10 and 20 are simultaneously formed on the upper faces of the tungsten films 9 and 19, the gates MG, SGD and PG are formed by performing a gate processing.

In the gate processing of the memory cell area, the silicon nitride film 10 is patterned as a mask, and the tungsten film 9, the tungsten nitride film 8, the polysilicon film 7, the inter-electrode insulating film 6, and the polysilicon film 5 are anisotropically etched by the RIE method, and the gates MG and SGD are separated from one another and thus formed. After the gate processing, by the ion implantation method, dopants are introduced into the surface of the semiconductor substrate 2 between the gates MG and SGD, and the diffusion areas 2a and 2b, and the like are formed.

Simultaneously, the gate of the peripheral transistor Trp of the peripheral circuit area is processed, the same processing is performed to the films 14 to 20. Specifically, the silicon nitride film 20 is patterned as a mask, and the tungsten film 19, the tungsten nitride film 18, the polysilicon film 17, the inter-electrode insulating film 16, and the polysilicon film 15 are anisotropic etched by the RIE method, and the gate PG is separated and formed. After the gate processing, by the ion implantation method, the dopants are introduced into the surface of the semiconductor substrate 2 at the base of the gate PG, and the diffusion area 2d is formed. In the memory cell area and the peripheral circuit area, the gate processing may be performed at the same time, or may be individually performed. Hereby, it is possible to obtain the structures shown in FIG. 3A to FIG. 3C. Thereafter, although not shown, an interlayer insulating film is formed so as to cover the upper faces of the respective gates MG and SGD, and the NAND type flash memory device 1 is formed by forming the contact or the like.

According to the embodiment, since the width W2 of the opening 21 at the time of processing the gate PG, is formed to be wider than the width W1 of the opening 11 at the time of processing the gate SGD, and the tungsten nitride film 18 is formed until it comes into contact with the side face of the polysilicon film 17, it is possible to widen a contact area between the tungsten nitride film 18 and the polysilicon film 15, and it is possible to achieve a low resistance structure.

Even if the film corresponding to the polysilicon film 12 is formed on the opening 21 of the area R1 shown in FIG. 3B, there is a possibility that the p-type dopant (for example, boron (B)) which is doped into the polysilicon film 17 will diffuse up to the polysilicon film 15 through the polysilicon film 12, and increase the interface resistance. In the embodiment, since the film corresponding to the polysilicon film 12 is not formed in the area R1, it is possible to effectively use a contact interface between the tungsten nitride film 18 and the polysilicon film 15 as an electrical conduction face, and it is possible to achieve the low resistance structure.

Moreover, since the tungsten film 19 overlies the side face of the inter-electrode insulating film 16 with the tungsten nitride film 18 therebetween, for example, when the p-type impurities are introduced into the polysilicon film 17, a diffusion path of the impurities is blocked by the tungsten nitride film 18 and the tungsten film 19. As a result, it is possible to suppress impurity diffusion to the polysilicon film 15 from the polysilicon film 17. Hereby, it is possible to suppress the high resistivity of the gate electrode PG.

By making the configuration of stacking the tungsten film 9 over the tungsten nitride film 8 on the upper face of the polysilicon film 7, where the tungsten film 9 becomes the control electrode CG of the memory cell MT through the tungsten nitride film 8, it is possible to achieve a low resistance structure for the word line WL. Moreover, it is possible to form the polysilicon film 7 thinly. As a result, it is possible to enhance the ease of processing by lowering an aspect ratio at the time of the gate processing.

In addition, according to the embodiment, the polysilicon film 12 of the film thickness T0 which is thicker than ½ of the width W1 of the opening 11 of the inter-electrode insulating film 6, is formed, and the case of generating the level difference which is caused by the concave portion 5a in the upper face of the polysilicon film 12, is reduced.

Thereafter, by etching-back the polysilicon film 12 in accordance with the etching process, the upper faces of the polysilicon films 7 and 12 are formed to be substantially flat. Hereby, it is possible to enhance flatness. Therefore, at the time of the film formation of the tungsten nitride film 8 on the upper face of the polysilicon film 7, it may be configured without generating a discontinuity.

### Second Embodiment

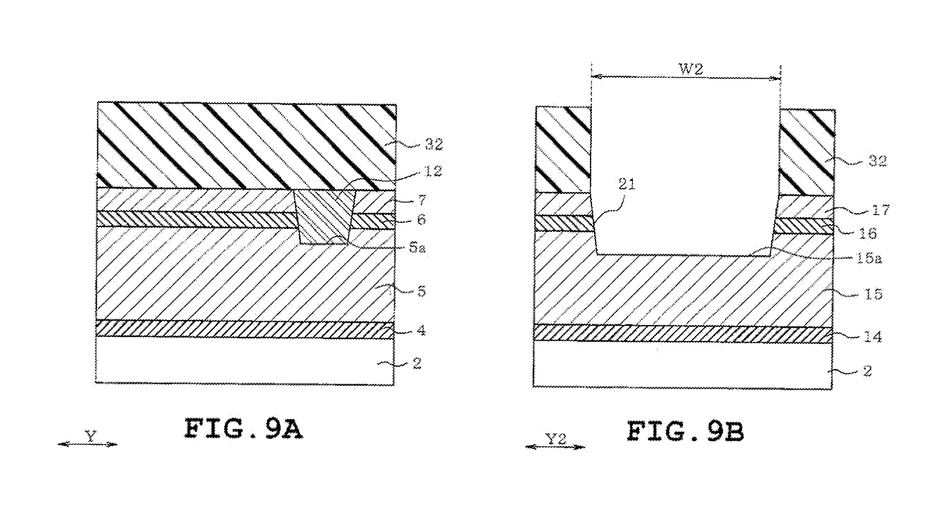

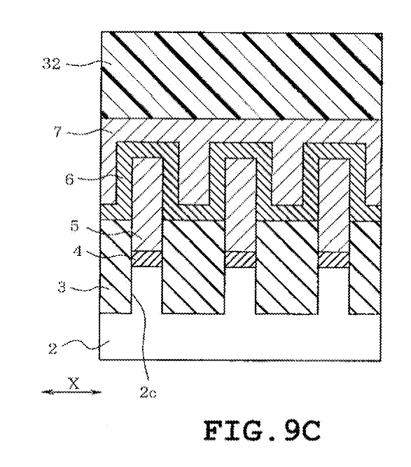

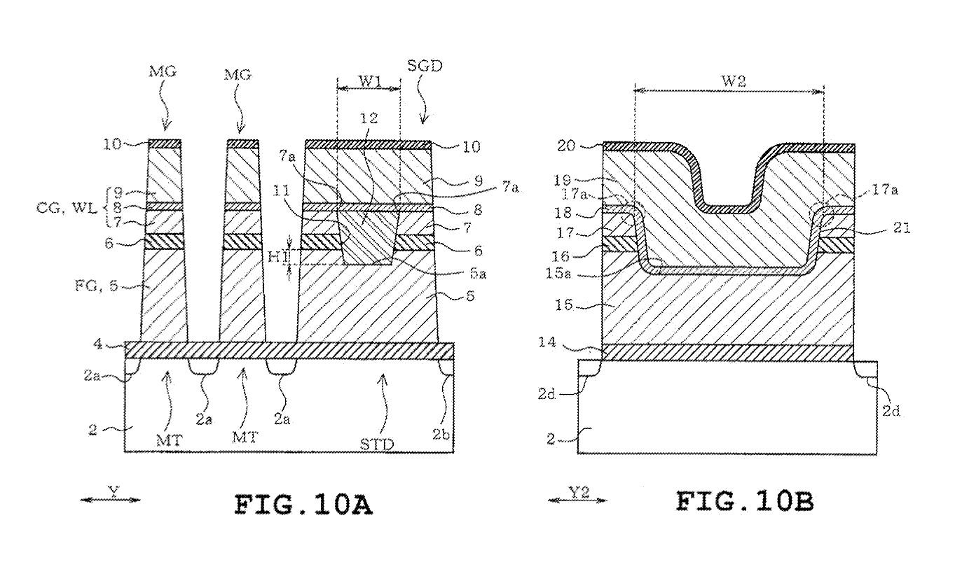

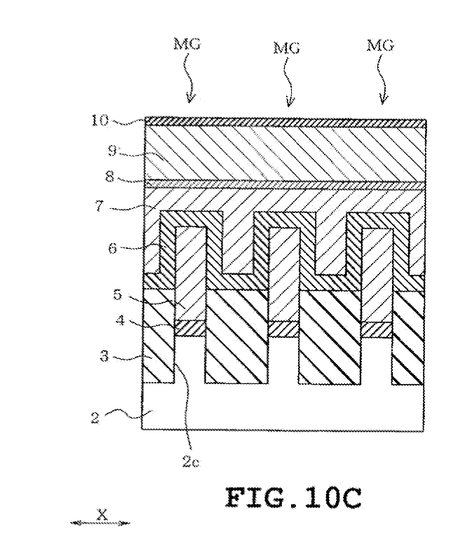

FIG. 10A to FIG. 14C depict a second embodiment. Hereinafter, the portions of the second embodiment which are different from the first embodiment will be described.

In the second embodiment, as shown in FIG. 10A to FIG. 10B, an upper side corner portion 17a of the polysilicon film 17 defining an upper end of the opening 21 of the gate PG of the peripheral transistor Trp, is smoothly curved (rounded) in comparison with an upper side corner portion 7a of the polysilicon film 7 defining the upper end of the opening 11 of the select transistor STD.

That is, according to the embodiment, since the upper side corner portion 17a of the polysilicon film 17 is formed to be rounded or curved at the edge of the opening 21 into the polysilicon film 17, it is possible to suppress the forming of a discontinuity in the tungsten nitride film 18.

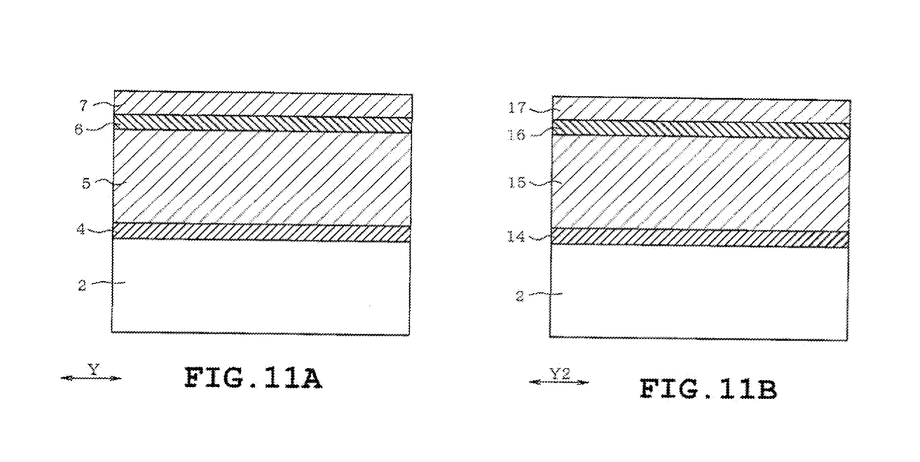

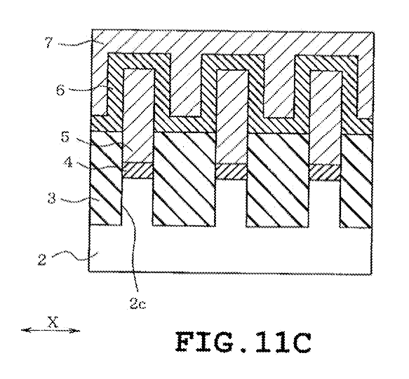

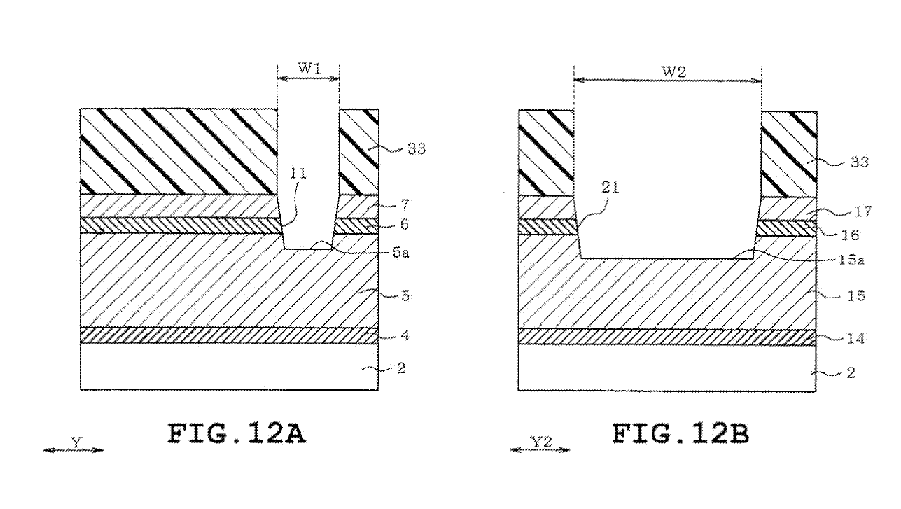

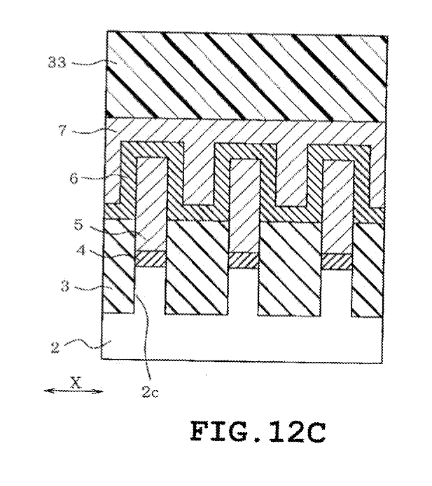

Next, regarding the manufacturing process of the structure, the portions which are different from the first embodiment, will be described. The second embodiment is formed the same as the first embodiment at FIG. 5A to FIG. 5C of the first embodiment. FIG. 11A to FIG. 11C show the same structure as is shown in FIG. 5A to FIG. 5C.

As shown in FIG. 12A to FIG. 12C, in the area corresponding to the gate SGD of the select transistor STD, the opening 11 and the concave portion 5a are formed using patterned masks, formed by photolithography, such as hard masks and/or a resist layer, followed by anisotropic etching. Moreover, simultaneously, in the area corresponding to the gate PG of the peripheral transistor Trp, the opening 21 and the concave portion 15a are formed using patterned masks, formed by photolithography, such as hard masks and/or a resist layer, followed by anisotropic etching. At this point, the width dimension of the opening 11 is the width W1, and the width dimension of the opening 21 is set to the width W2 (>W1). The opening sizes are based on the size of the openings in the patterned mask layer. Since the number of processes is reduced, the process of forming the openings 11 and 21 may be performed at the same time, but they may be performed separately. After the etch processing, the surfaces of the opening 11 and the concave portion 5a, and the opening 21 and the concave portion 15a, are wet cleaned.

Next, as shown in FIG. 13A to FIG. 13C, so as to fill up the inside of the opening 11 and the concave portion 5a, and the opening 21 and the concave portion 15a, an un-doped polysilicon film 12 is formed at the predetermined film thickness T0 (for example, 40 nm), for example, using the CVD method.

The film thickness T0 at the time of the film formation of the polysilicon film 12, is set to be larger than ½ of the dimension W1 of the opening 11 (T0>W1/2). Moreover, the film thickness T0 at the time of the film formation of the polysilicon film 12, is set to be smaller than ½ of the width W2 of the opening 21. The polysilicon film 12 is formed at the same conditions as the first embodiment. After forming the polysilicon film 12, in the upper face of the polysilicon film 12 of the select gate SGD, a slight level difference is generated in the position corresponding to the concave portion 5a, but the depth dimension h of the level difference is sufficiently small in comparison with the depth H1 of the concave portion 5a, and the dimension h is set to, for example, 10 nm or less. On the other hand, in the upper face of the polysilicon film 15 of the gate PG, the polysilicon film 12 is conformally formed along exposed faces of the opening 11 and the concave portion 5a.

Next, as shown in FIG. 14A to FIG. 14C, the polysilicon film 12 is processed by isotropic dry etching (for example, a CDE (Chemical Dry Etching) method), and the polysilicon film 12 which is formed within the opening 21 and the concave portion 5a in the peripheral region, is removed. At this point, as shown in FIG. 14A, the polysilicon film 12 within the opening 11 of the select gate SGD, remains.

As shown in FIG. 14B, in the forming area of the gate PG of the peripheral transistor Trp, since the polysilicon film 12 is evenly formed within the opening 21 and the concave portion 15a, the polysilicon film 12 may be evenly removed by performing the isotropic etching processing. Furthermore, after the removal processing, due to an effect of the isotropic etching processing, the upper side corner portion 17a of the polysilicon film 17 is slightly removed. As a result, the upper side corner portion 17a is rounded or curved (see FIG. 14B). At this time, the upper side corner portion 17a has a convex face on the upper side.

In the forming area of the select gate SGD, by timing the isotropic dry etching processing, when the upper face of the polysilicon film 7 is exposed, the upper face of the polysilicon film 12 and the upper face of the polysilicon film 7 may be substantially flat and flush with one another, i.e., co-planar or substantially co-planar. As described above, this occurs because at the time of the film formation of the polysilicon film 12, the level difference dimension h of the upper face of the polysilicon film 12 is small.

Thereafter, the substrate 2 is heated to activate the dopants in the polysilicon layers, are activated, and the tungsten nitride film 8 and the tungsten film 9 are then formed by the sputter method, on the upper faces of the polysilicon films 7, 12, 15 and 17. Since the upper faces of the polysilicon films 7 and 12 are formed in substantially the flat state, the tungsten nitride film 8 configuring the select gate SGD, may be formed in substantially the uniform film thickness without generating a discontinuity (a ledge step of indentation). The tungsten film 9 is formed over the tungsten nitride film 8, and reaction of the tungsten with the polysilicon films 7, 12 is suppressed.

Moreover, in the forming area of the gate PG of the peripheral circuit area, since the tungsten nitride film 8 contacts a curved (rounded) surface of the upper side corner portion 17a of the polysilicon film 17, it may be formed without having a thickness variation or discontinuity which may occur where the side corner portion is a sharp corner.

Next, as shown in FIG. 10A to FIG. 10C, in the same manner as the first embodiment, after the silicon nitride films 10 and 20 are formed on the upper face of the tungsten film 9, the gates MG, SGD and PG are formed. Furthermore, after the gates are formed, using the ion implantation method, dopants are introduced into the surface of the semiconductor substrate 2 between the gates MG and SGD, and the surface of the semiconductor substrate 2 at the base of the gate PG, and the diffusion areas 2a, 2b and 2d are formed. Hereby, it is possible to obtain the structure shown in FIG. 10A to FIG. 10C. Thereafter, although not shown, the interlayer insulating film is formed so as to cover the upper faces of the respective gates MG and SGD, and the NAND type flash memory device 1 is formed by forming the contact or the like.

According to the second embodiment described above, the same effect as the first embodiment may be obtained, and the upper side corner portion 17a which becomes the corner portion of the upper face of the polysilicon film 17 at the opening, is formed to be curved or rounded. Therefore, it is possible to reduce the possibility that the tungsten nitride film 18 has a discontinuity or thickness variation.

### Third Embodiment

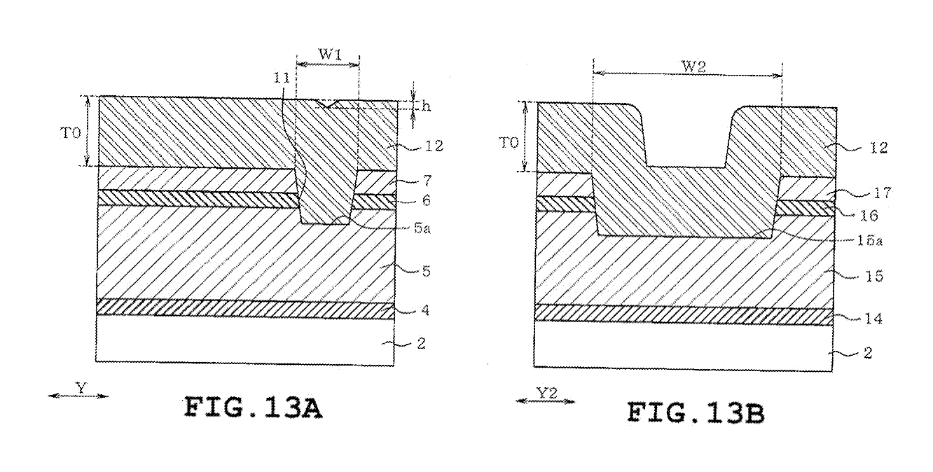

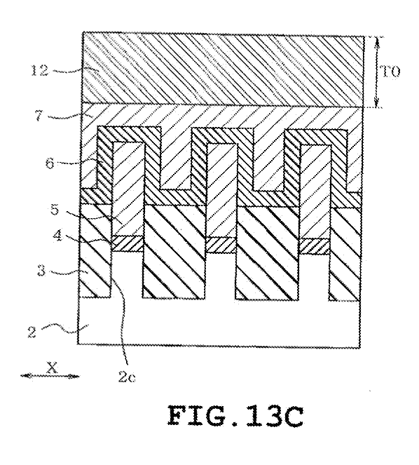

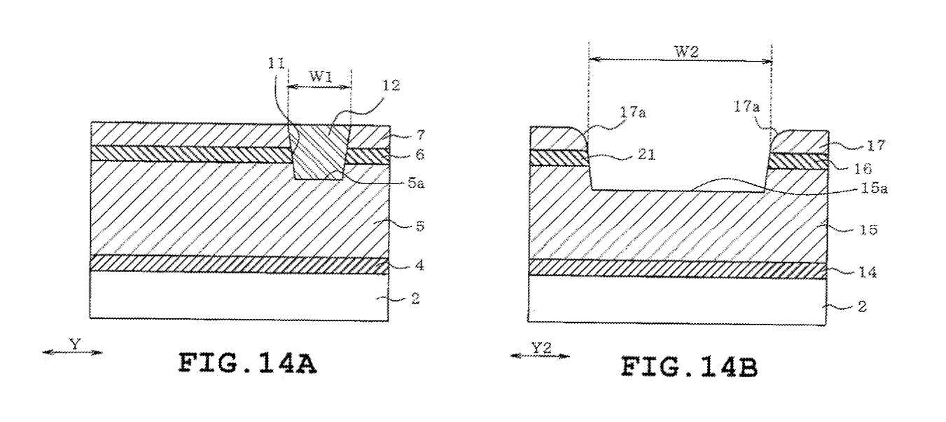

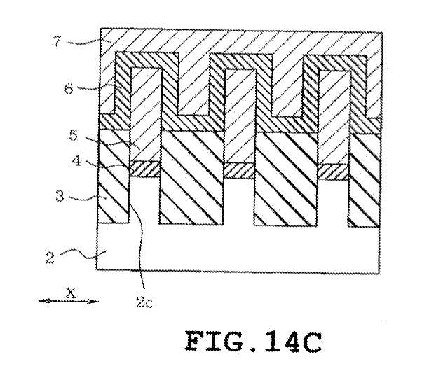

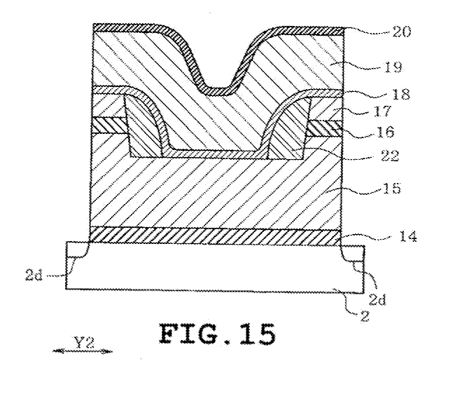

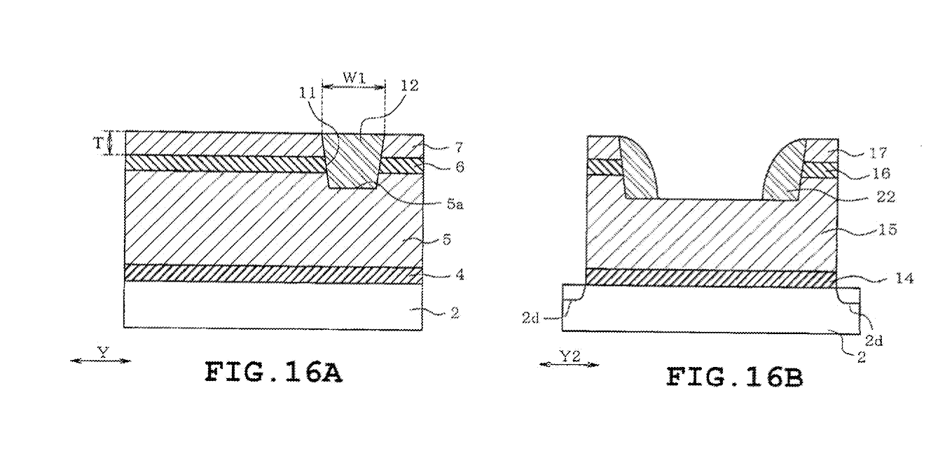

FIG. 15, FIG. 16A, and FIG. 16B show a third embodiment. FIG. 15 shows a structure example of the same portion of a device as is shown in FIG. 3B, and a polysilicon film 22 is formed along the sidewall of the opening and covers the exposed ends of the polysilicon films 15 and 17 at the opening 21 sidewall.

As shown in FIG. 15, the polysilicon film 22 is positioned on the wall of the opening between the tungsten nitride film 18 and the polysilicon films 15 and 17, and the polysilicon film 22 contacts the polysilicon films 15 and 17 at the wall of the opening 21. The polysilicon film 22 is the polysilicon film which is formed simultaneously with, or before and after the film formation of the polysilicon film 12 of the first embodiment or the second embodiment.

The polysilicon film 22 is an un-doped film at the time of the film formation. That is, using the reference drawings of the second embodiment, when the opening 11 shown in FIG. 12A is formed, the opening 21 of the wide width is formed simultaneously therewith, or before and after the process thereof shown in FIG. 12B, and the polysilicon films 12 and 22 are formed within the openings 11 and 21, respectively. Thereafter, if the polysilicon films 12 and 22 are etched back using an anisotropic conditions (see FIG. 16A), as shown in FIG. 16B, a portion of the polysilicon film 16 may remain covering the end of the polysilicon films 17 and 15 and the inter-electrode insulating film 16a at the side wall of opening 21.

That is, the polysilicon film 22 has the structure in which the portion thereof remains along the X direction of an inside wall of the opening 21 of the polysilicon film 17 and the inter-electrode insulating film 16. For example, when the p-type impurities are introduced into the polysilicon film 17, and the n-type impurities are introduced into the polysilicon film 15, if the heat processing is performed by heating the substrate, although the polysilicon film 22 is un-doped, dopants are diffused from the adjacent doped polysilicon film as described above.

Therefore, there is the case where the n-type impurities which are introduced into the polysilicon film 15, are diffused to the lower portion of the polysilicon film 22. In this case, the lower portion of the polysilicon film 22 and the polysilicon film 15 are formed in the same conductive type. Moreover, the concentration of the n-type dopant in the lower portion of the polysilicon film 22 is smaller than the concentration of the n-type dopant in the polysilicon film 15.

In addition, there is the case where the p-type dopant in the polysilicon film 17 diffuse into the upper portion of the polysilicon film 22. In this case, the upper portion of the polysilicon film 22 and the polysilicon film 17 are formed in the same conductive type. Moreover, the concentration of the p-type dopants in the upper portion of the polysilicon film 22, is less than the concentration of the p-type dopants in the polysilicon film 17.

In the embodiment, the polysilicon film 22 contacts the polysilicon films 15 and 17, and the tungsten nitride film 8 contacts the upper face of the concave portion 5a of the polysilicon film 5 in the center portion. As a result, it is possible to lower the contact resistance between the tungsten nitride film 8 and the polysilicon film 5.

Moreover, since the polysilicon film 22 is formed over the entire side wall of the opening 21, it is possible to reduce the concentration of the dopants which are diffused into to the polysilicon film 15 from the polysilicon film 17. As a result, it is possible to reduce the resistance of the gate electrode PG.

### Fourth Embodiment

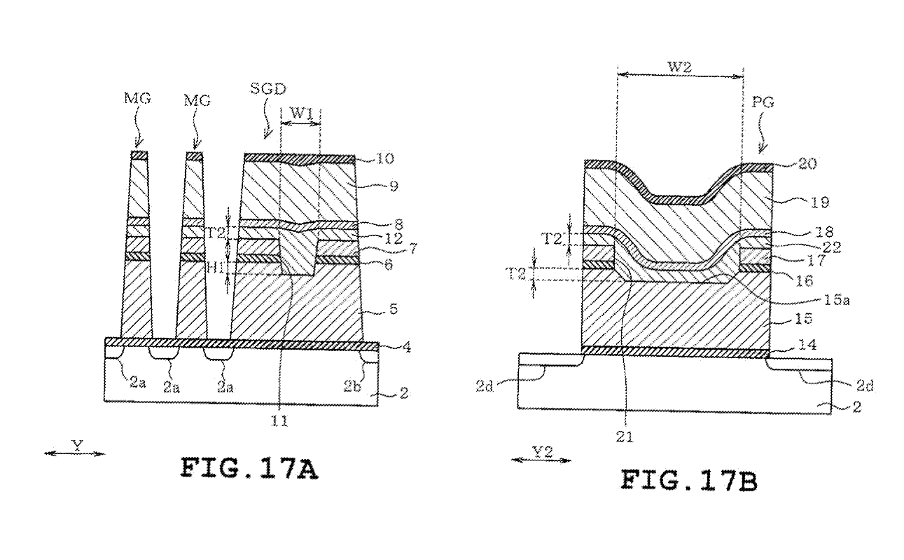

FIG. 17A and FIG. 17B show a fourth embodiment. A point in which the fourth embodiment is different from the embodiments described above is the point where the polysilicon film 12 is formed on the polysilicon film 7 within the select gate SGD. Additionally, the polysilicon film 22 as a first material fills the inside of the concave portion 15a of the polysilicon film 15 within the gate PG, and is formed on the polysilicon film 17.

As shown in FIG. 17A, the polysilicon film 12 extends, in the opening 11, between the polysilicon film 5 and the tungsten nitride film 8. The polysilicon film 12 is the film which is formed in the same processes as the polysilicon film 12 of the first to the third embodiments. The polysilicon film 12 is also formed inside the concave portion 5a, at the base of the opening 11, of the polysilicon film 5, and inside the openings 11, and on the upper face of the polysilicon film 7. When the film thickness T of the polysilicon film 12 is formed with respect to the opening width W1 of the opening 11, the film thickness T0 at the time of the film formation is formed so as to be T0>W1/2, and it may be etched back. As a result, there is the case where the polysilicon film 12 becomes T2 which is the film thickness on the upper face of the polysilicon film 7 (T2≦W1/2).

As shown in FIG. 17B, the polysilicon film 22 is interposed between the polysilicon film 15 and the tungsten nitride film 18. In the same manner as the third embodiment, the polysilicon film 22 is the film which is formed simultaneously with, or before and after the process of, the polysilicon film 12 of the first embodiment or the second embodiment. The polysilicon film 22 is formed in the concave portion 15a of the polysilicon film 15 and in the openings 21, and on the upper face of the polysilicon film 17. In the polysilicon film 22, the film thickness on the upper face of the polysilicon film 17 is T2. Moreover, in the opening 21, the film thickness of the polysilicon film 22 in the portion of which the upper face is flat (the vicinity of the center of the opening 21), becomes T2. Here, the film thickness T2 is smaller than the depth of the opening 21 (distance to the upper face of the polysilicon film 15 which is exposed by the opening 21 from the upper face of the polysilicon film 17). Additionally, it may be said that the film thickness of the polysilicon film 22 in the vicinity of the center of the opening 21 is thinner than the film thickness of the polysilicon 12 in the opening 11.

For example, when the p-type dopants are introduced into the polysilicon film 17, and the n-type dopants are introduced into the polysilicon film 15, if the heat processing is performed although the polysilicon film 22 is deposited in an un-doped condition, each impurity described above is diffused. Therefore, there is the case where the n-type impurities which are introduced into the polysilicon film 15, are diffused in the lower portion of the polysilicon film 22. In this case, the lower portion of the polysilicon film 22 and a polysilicon film 15 are formed as the same conductive type. Additionally, the concentration of the n-type dopant in the lower portion of the polysilicon film 22 is less than the concentration of the n-type dopant which is introduced into the polysilicon film 15.

Moreover, in the polysilicon film 22 which is formed on the polysilicon film 17, there is the case where the p-type dopants which are introduced into the polysilicon film 17, are diffused. In this case, the polysilicon film 22 on the polysilicon film 17, and the polysilicon film 17 are formed of the same conductivity type. In addition, the concentration of the p-type dopants in the polysilicon film 22 on the polysilicon film 17 is less than the concentration of the p-type dopants which are introduced into the polysilicon film 17.

Moreover, in the vicinity of the center of the opening 21, the film thickness of the polysilicon film 22 is less than the depth of the opening 21. Therefore, it is possible to reduce the concentration of the dopants which are diffused into the polysilicon film 15 in the vicinity of the center of the opening 21 from the polysilicon film 17. As a result, it is possible to reduce the resistance of the gate electrode PG.

### Other Embodiments

It is possible to make the following modifications in addition to the description in the embodiments described above.

In the first embodiment, the embodiment in which the tungsten nitride film 18 comes into contact with the overall face of the side wall of the inter-electrode insulating film 16, is shown, but the tungsten nitride film 18 may come into contact with at least the portion of the side wall (side face) of the inter-electrode insulating film 16. It may only need come into contact and cover only the upper face of the concave portion 15a of the polysilicon film 15, and it is still possible to prevent the diffusion of the dopants from the polysilicon film 15 into the polysilicon film 17.

In the second embodiment, the embodiment in which an upper limit of the film thickness T0 is set to be smaller than ½ of the dimension of the width W2, and the polysilicon film 12 is evenly formed within the opening 21 and the concave portion 15a, and the polysilicon film 12 is removed by isotropic etching at the same time in the forming area of the select gate SGD and the gate PG, is shown, but the upper limit of the film thickness T0 is not limited thereto. The predetermined film thickness which is the above film thickness or more, may be set in consideration of the process capability. For example, even when the film thickness T0 is made further thicker than the dimension of the width W2, the polysilicon film 12 may be removed, for example, using the process of selectively etching the polysilicon film 12 within the gate PG. Furthermore, the polysilicon film 12 within the gate PG may not be entirely removed. The insulating film may be configured by combining dielectric material films of various kinds.

If the barrier metal film is the material suppressing the reaction with the metal film and a polycrystalline silicon film, in addition to tungsten nitride (WN), various materials such as tungsten silicide nitride (WSiN), titanium nitride (TiN), ruthenium (Ru), ruthenium oxide (RuO), tantalum (Ta), tantalum nitride (TaN), tantalum nitride silicide (TaSiN), manganese (Mn), manganese oxide (MnO), niobium (Nb), niobium nitride (NbN), molybdenum nitride (MoN), and vanadium (Vn) may be used as a barrier.

In addition to tungsten (W), the metal film may use materials such as tungsten silicide (WSi), molybdenum (Mo), and tantalum (Ta), or combinations thereof or materials using these materials as main ingredients.

Moreover, the combination of the barrier metal film and the metal film, may be carried out as the various combinations using the various materials described above, in addition to the combination of the tungsten nitride (WN) film and the tungsten (W) film.

The embodiments are applied to the NAND type flash memory device 1, but may be applied to an NOR type flash memory device, and a nonvolatile semiconductor storage device such as EEPROM. Additionally, the embodiments may be applied to the case where the memory cell is configured as 1 bit, and the case where the memory cell is configured as a plurality of bits.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate;
a first insulating film on the semiconductor substrate;
a first electrode film on the first insulating film;
a second insulating film on the first electrode film;
a second electrode film on the second insulating film;
an opening extending through the second electrode film and the second insulating film and into the first electrode film;
a barrier film over the surfaces of the opening and a portion of the first electrode film exposed within the opening; and
a metal film disposed on the barrier film disposed over the surfaces of the opening;
wherein the barrier film directly contacts at least a portion of the second insulating film exposed in the opening and the metal film overlies the location where the barrier film directly contacts the second insulating film exposed in the opening.

2. The semiconductor device according to claim 1,
wherein the barrier film overlies portions of the first electrode film and the second electrode film exposed within the opening, and the metal film overlies the portions of the first electrode film and the second electrode film.

3. The semiconductor device according to claim 1,
wherein the first electrode film is a polysilicon film of a first conductivity type, and
the second electrode film is a polysilicon film of a second conductivity type.

4. The semiconductor device according to claim 1, wherein the barrier film and the metal film fill the opening.

5. A semiconductor device comprising:
on a first area of a semiconductor substrate,
a first insulating film;
a first electrode film on the first insulating film;
a second insulating film on the first electrode film;
a second electrode film on the second insulating film; and
a first opening extending through the second electrode film and the second insulating film and into the first electrode film, and having a first opening width;
on a second area of the semiconductor substrate,
a third insulating film;
a third electrode film on the third insulating film;
a fourth insulating film on the third electrode film;
a fourth electrode film on the fourth insulating film; and
a second opening extending through the fourth electrode film and the fourth insulating film, and having a second opening width which is less than the first opening width;
a first barrier film and a first metal film in the first opening; and
a first material, different than the first metal film, in the second opening,
wherein, on the first area of the semiconductor substrate, the first barrier film overlies at least a portion of the second insulating film exposed within the opening and the metal film overlies the barrier film overlying the portion of the second insulating film exposed within the opening.

6. The semiconductor device according to claim 5,
wherein the first electrode film is a polysilicon film of a first conductivity type, and
the third electrode film is a polysilicon film of a second conductivity type which is different than the first conductivity type.

7. The semiconductor device according to claim 6,
wherein the first conductivity type is n-type, and the second conductivity type is p-type.

8. The semiconductor device according to claim 5, further comprising:
a second barrier film on an upper face of the first material and an upper face of the third electrode; and
a second metal film on the second barrier metal film.

9. The semiconductor device according to claim 5, further comprising:
a memory cell on a third area of the semiconductor substrate that is different from the first and the second areas, and adjacent to the second area, the memory cell including:
a sixth insulating film;
a sixth electrode film on the sixth insulating film;
a seventh insulating film on the sixth electrode film; and
a seventh electrode film on the seventh insulating film.

10. The semiconductor device according to claim 9,
wherein the conductivity type of the sixth electrode film and the first electrode film are different.

11. The semiconductor device according to claim 9,
wherein the conductivity type of the seventh electrode film and the second electrode film are the same.

12. The semiconductor device according to claim 11,
wherein the conductivity type of the seventh electrode film and the sixth electrode film are the same.

13. The semiconductor device according to claim 8, wherein
the third electrode film and the first material are a polysilicon film of a second conductivity type, and
the dopant concentration of the first material is less than the dopant concentration of the third electrode film.

14. The semiconductor device according to claim 8, wherein
the fourth electrode film and the first material are a polysilicon film of a second conductivity type, and
the dopant concentration of the first material is less than the dopant concentration of the fourth electrode film.

15. The semiconductor device according to claim 14,
wherein the second conductivity type is a p-type.

16. The semiconductor device according to claim 5,
wherein a corner portion of an upper face of the second electrode within the first opening has a greater curvature than a corner portion of the fourth electrode within the second opening.

17. A nonvolatile semiconductor storage device comprising:
a memory cell and a peripheral transistor on a semiconductor substrate, wherein
the peripheral transistor includes:
a first insulating film on the semiconductor substrate;
a first electrode film of a first conductivity type on the first insulating film;
a second insulating film on the first electrode film;
a second electrode film on the second insulating film;
an opening extending through the second electrode film and the second insulating film, and into the first electrode film; and
a first material filling the opening and contacting the first electrode film,
wherein at least a portion of the first material adjacent to the first electrode film is of the first conductivity type, and a barrier metal film and a metal film that are formed on the first material, and
the memory cell includes:
a third insulating film on the semiconductor substrate;
a third electrode film of the first conductivity type on the third insulating film;
a fourth insulating film on the third electrode film;
a second material on the fourth insulating film; and
a fourth electrode film on an upper face of the second material,
wherein a film thickness of a portion on an upper face of the second electrode film of the first material is equal to a film thickness of the second material.

18. The nonvolatile semiconductor storage device according to claim 17, wherein
the first electrode film is a polysilicon film of the first conductivity type, and
the second electrode film is a polysilicon film of the first conductivity type.

19. The nonvolatile semiconductor storage device according to claim 17,
wherein the barrier metal film directly contacts the upper face of the first material.

20. The nonvolatile semiconductor storage device according to claim 17,
wherein the first material is formed so that the film thickness of the portion on the upper face of the second electrode film is one-half or less of a width dimension of the opening.
